(19) United States
(12) Patent Application Publication
(10) Pub. No.: US 2011/0007012 A1
(43) Pub. Date: Jan. 13, 2011

(54) DISPLAY PANEL AND TOUCH-RESPONSIVE DISPLAY ASSEMBLY

(75) Inventor: PO-SHENG SHIH, Miao-Li County (TW)

Correspondence Address: Altis Law Group, Inc.;ATTN: Steven Reiss, 288 SOUTH MAYO AVENUE, CITY OF INDUSTRY, CA, 91789, US

(73) Assignee: CHIMEI INNOLUX CORPORATION, Miao-Li County (TW)

(21) Appl. No.: 12/825,341

(22) Filed: Jun. 29, 2010

(30) Foreign Application Priority Data
Jul. 10, 2009 (CN) 200910304235.9

(51) Int. Cl. G06F 3/041; H01L 51/52

(52) U.S. Cl. 345/173; 257/40; 977/952; 977/742; 257/E51.018

(57) ABSTRACT

A touch-responsive display assembly includes a touch panel. The touch panel includes: an anode, a cathode disposed over the anode, and an organic layered structure disposed between the anode and the cathode and including an organic electroluminescent layer that is emissive when a voltage is applied across the anode and the cathode. At least one of the anode and the cathode is made of a flexible film of a conductive nanomaterial that contains interconnected nanounits.

### BACKGROUND

1. Technical Field

The present disclosure relates to a display panel and a touch-responsive display assembly, and more particularly to a display panel and a touch-responsive display assembly including the display panel having at least one electrode that includes a nanomaterial.

2. Description of Related Art

A conventional organic electroluminescence display, which is also called organic light emitting diode (OLED) display, includes a substrate, an anode disposed on the substrate, a hole transport layer, an organic emitting layer, an electron transport layer, an electron injection layer, and a cathode. In operation, when a voltage is applied across the anode and the cathode, the anode gives electron holes to the organic emitting layer through the hole transport layer and the cathode gives electrons to the organic emitting layer through the electron injection layer and the electron transport layer. The electrons and the holes recombine in the organic emitting layer, thereby resulting in emission of light. The anode includes a conductive material with a high working function, such as indium tin oxide (ITO), tin oxide, or zinc oxide. Hence, the conventional OLED normally involves the use of a transparent substrate formed with an ITO film which serves as the anode. One advantage of the conventional OLED over other types of displays is that it can be flexible when using a flexible substrate. However, the ITO film serving as the anode of the conventional OLED tends to be severely deformed and damaged when the conventional OLED is bent.

### SUMMARY

According to one aspect of the present disclosure, there is provided a display panel that comprises: an anode; a cathode disposed over the anode; and an organic layered structure disposed between the anode and the cathode and including an organic electroluminescent layer that is emissive when a voltage is applied across the anode and the cathode. At least one of the anode and the cathode is made of a flexible film of a conductive nanomaterial that contains interconnected nanounits.

According to another aspect of the present disclosure, there is provided a touch-responsive display assembly that comprises: a first electrode unit; a second electrode unit disposed over the first electrode unit; a third electrode unit disposed between the first and second electrode units; and an organic layered structure disposed between the first and third electrode units and having an organic electroluminescent layer that is emissive when a voltage is applied across the first and third electrode units. The second electrode unit is electrically coupled to the third electrode unit and cooperates with the third electrode unit to form a touch panel that is touch-responsive. At least one of the first, second and third electrode units includes a flexible film of a conductive nanomaterial that contains interconnected nanounits.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is a schematic side view of the first exemplary embodiment of a display panel of the present disclosure.

FIGS. 2A and 2B are perspective views to illustrate consecutive steps of how a material for an anode of the first exemplary embodiment can be prepared.

FIG. 2C is a schematic side view of the material for the anode of the first exemplary embodiment.

FIG. 2D is a schematic top view of the material for the anode of the first exemplary embodiment.

FIG. 3 is a schematic side view of the second exemplary embodiment of a display panel of the present disclosure.

FIG. 4 is a schematic side view of the third exemplary embodiment of a display panel of the present disclosure.

FIG. 5 is a schematic side view of the fourth exemplary embodiment of a display panel of the present disclosure.

FIG. 6 is a schematic side view of the first exemplary embodiment of a touch-responsive display assembly of the present disclosure.

FIG. 7 is a schematic side view of the second exemplary embodiment of a touch-responsive display assembly of the present disclosure.

### DETAILED DESCRIPTION

Reference will now be made to the drawings to describe various embodiments in detail.

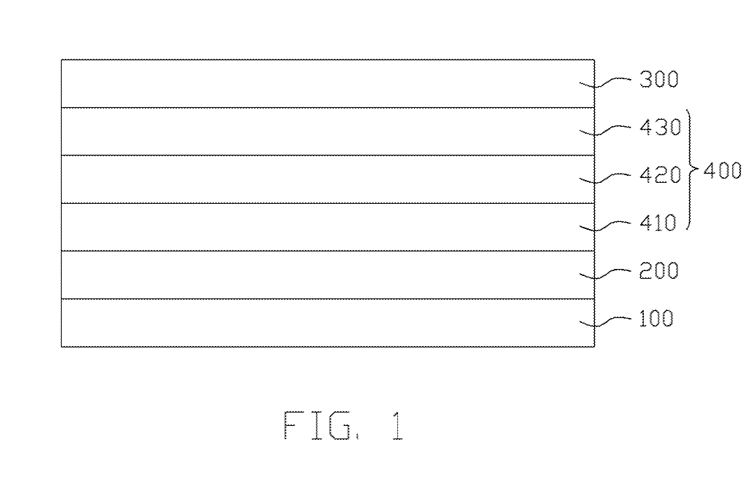

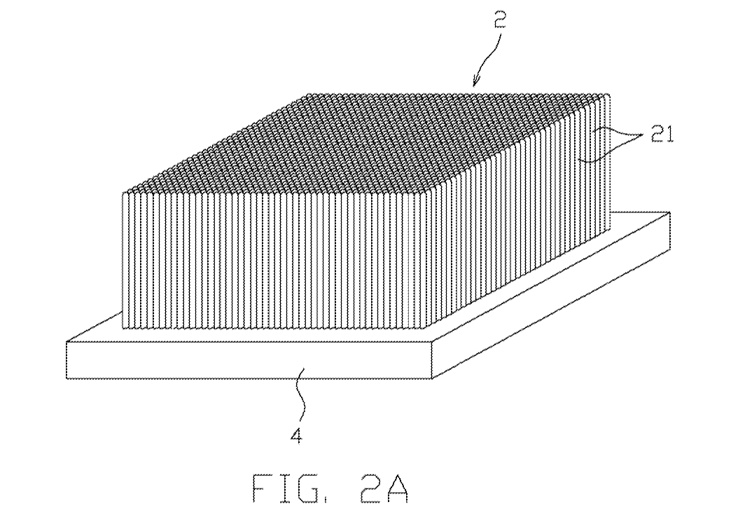

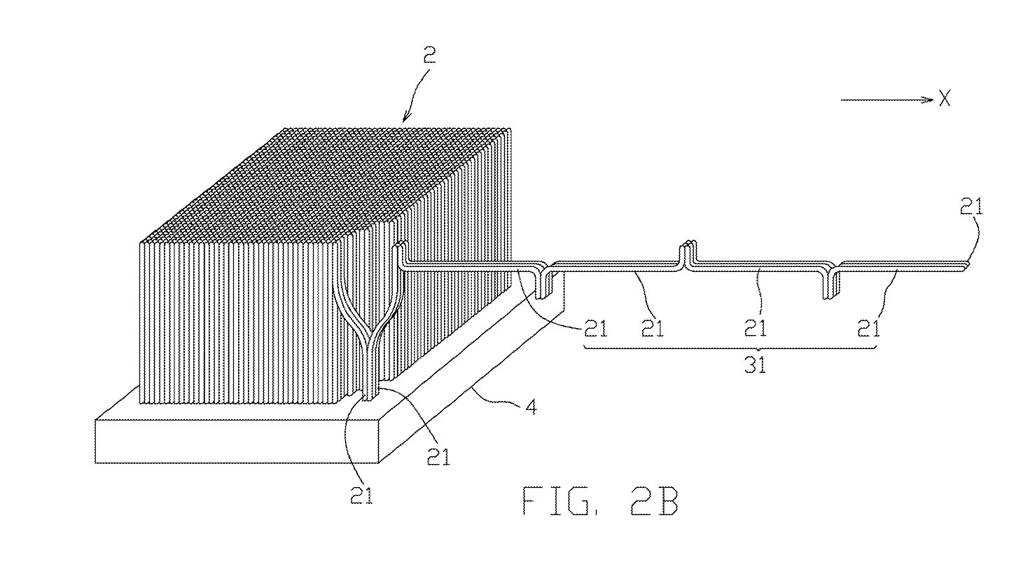

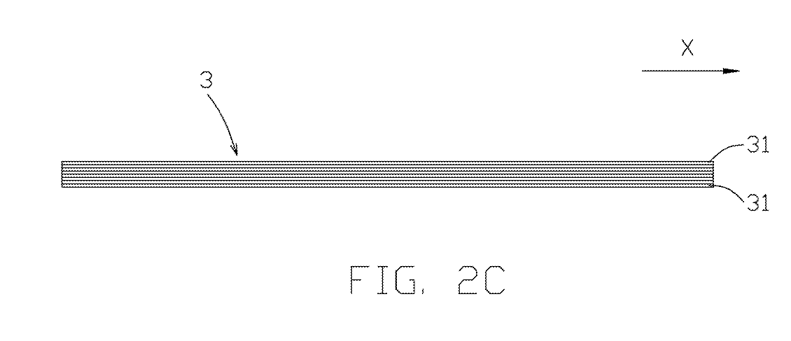

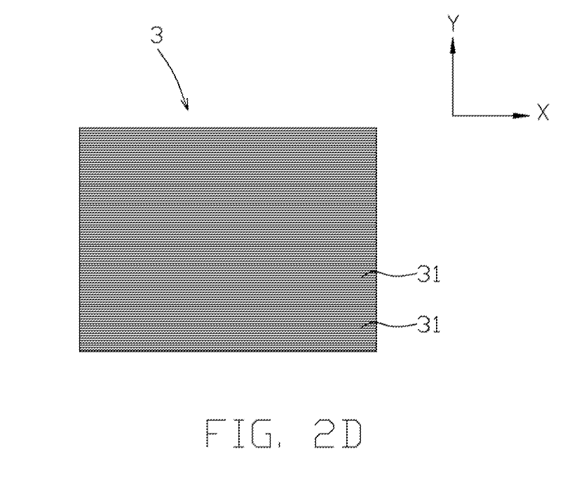

Referring to FIG. 1, in combination with FIGS. 2A to 2D, the first exemplary embodiment of a display panel of the present disclosure includes: a lower substrate 100; an anode 200 disposed on the lower substrate 100; a cathode 300 disposed over the anode 200; and an organic layered structure 400 disposed between the anode 200 and the cathode 300 and including a hole transport layer 410, an electron transport layer 430, and an organic electroluminescent layer 420 that is sandwiched between the hole transport layer 410 and the electron transport layer 430 and that is emissive when a voltage is applied across the anode 200 and the cathode 300. The anode 200 is sandwiched between the lower substrate 100 and the hole transport layer 410.

The lower substrate 100 can be a flexible transparent substrate of a polymeric material. Examples of the polymeric material include but are not limited to polymethylmethacrylate (PMMA) board, polyethylene terephthalate (PET) board, and polycarbonate (PC) board.

In the first exemplary embodiment, the anode 200 is transparent and is made of a flexible film 3 (see FIGS. 2C and 2D) of a conductive nanomaterial that contains strings 31 of interconnected nanounits 21 (see FIG. 2B). The flexible film 3 exhibits electric anisotropy (i.e., the flexible film 3 exhibits different resistivities in different directions). The interconnected nanounits 21 may be nanotube bundles, nanotubes or nanoparticles. In the embodiment, the interconnected nanounits 21 are carbon nanotube bundles. The carbon nanotube bundles extend along a stretching direction (X) (see FIG. 2B). The strings 31 of the interconnected nanounits 21 are substantially parallel to each other, and are distributed and aligned along a second direction (Y) transverse to the first direction (X). The flexible film 3 has a much higher conductivity or a much lower resistance in the first direction (X) than that in the second direction (Y). For example, the resistance of the flexible film 3 in the second direction (Y) to the first direction (X) is about 50˜350 times. The resistance of the flexible film 3 is between 1 Kilo-ohm per square and 800 Kilo-ohm per square based on the positions and the direction of the measurement. As illustrated in FIGS. 2A and 2B, the conductive nanomaterial of the conductive film 3 is prepared by forming a cluster 2 of the nanounits 21 on a supporting substrate 4 through deposition techniques, followed by pulling the nanounits 21 along the first direction (X) to make the nanounits 21 interconnected through Van der Waals' interaction to form the strings 31 and then stretching the strings 31 of the interconnected nanounits 21 to form the conductive nanomaterial.

The cathode 300 includes a conductive material having a low working function for enhancing injection rate of electrons given by the cathode 300 to the organic electroluminescent layer 420. The conductive material is made of metal or an alloy. Examples of metal suitable for the cathode 300 include but are not limited to Ag, Al, Li, Mg, Ca, In, for example. The alloy can be prepared, for instance, by vapor deposition of a chemically active metal with a low working function and a chemically stable metal with a high working function such that the chemically active metal and the chemically stable metal are mixed together in one single layer or are separated in different layers. Examples of the alloy include but are not limited to Mg/Ag, Li/Al, for example. In addition, the alloy can also includes an outer layer of aluminum and an inner layer of an ultra thin film of a metal oxide, such as LiF, Li₂O, MgO, Al₂O₃, for example. The alloy thus formed can enhance the light emitting efficiency of the display panel and improves the I-V characteristics curve of the display panel.

Alternatively, the cathode 300 can include a conductive material, such as the aforesaid nanomaterial of the flexible film 3, instead of the metal or alloy.

The hole transport layer 410 is made of a thermally stable transparent film that permits formation of a small energy barrier at an interface between the hole transport layer 410 and the anode 200 and that can achieve a structure free of pin holes when deposited through vacuum vapor deposition techniques. Examples of the hole transport layer 410 include but are not limited to aromatic tertiary amines.

The electron transport layer 430 is made of a transparent material that permits high electron transport rate and that exhibits good film forming ability and thermal stability. Examples of the electron transport layer 430 include but are not limited to aromatics with a large conjugated plane, such as Alq, PBD, Beq2, and DPVBi (the chemical names of the compounds can be referred to U.S. Pat. No. 6,433,355)

The organic electroluminescent layer 420 is made of a light-transmissible semiconductor material with a good film-forming property and a good thermal stability, and contains a fluorescent material with a high quantum efficiency. The semiconductor material can be polymers or low molecular weight organic compounds. The polymers are conductive or semi-conductive conjugated polymers with a molecular weight ranging from 10000 to 100000.

The polymers can be formed into a film using spin coating techniques, which is easy to conduct and which is cost effective. However, the purity of the polymers is required to be very high, which is difficult to be obtained. In addition, the resistance to degradation, the brightness and the color of the polymers are not competitive as compared to the low molecular weight organic compounds.

The low molecular weight organic compounds have a molecular weight ranging from 500 to 2000, can be formed into film by using vacuum vapor deposition techniques, and are organic dyes. The organic dyes are easy to be chemically modified, can be produced in a very high purity, and have a broad selectivity and a high quantum efficiency. Moreover, the organic dyes have various colors, including red, green and blue, for example. However, the organic dyes tend to suffer from degradation when used in a solid state, which can result in widening of the emission peak and red shift of the emission peak. Hence, the organic dyes are required to be blended in a matrix containing charges. The matrix is normally made of a material the same as that of the hole transport layer 410 or the electron transport layer 430.

Examples of the red dyes include but are not limited to Rhodamine, DCM, 2,4-dimethoxy-6-chloro-s-triazine (DCT), DCJT, DCJTB, DCJTI, and 1,1,4,4-tetrapheneyl-1,3-butadiene (TPBD) (the chemical names for the compounds DCM, DCJT and DCJTB and for the compound DCJTI can be referred to U.S. Pat. No. 5,935,720 and U.S. Pat. No. 7,582,508, respectively).

Examples of the green dyes include but are not limited to coumarin 6, quinacridone (qA), coronene, and naphthalimides.

Examples of the blue dyes include but are not limited to N-aryl-benzinidazole derivatives, 1,2,4-triazole (also used for electron transport layer 430), and distyrylarylene.

In use, when a forward bias voltage is applied to the display panel, holes from the anode 200 are injected into the organic electroluminescent layer 420 through the hole transport layer 410, and electrons are injected into the organic electroluminescent layer 420 through the electron transport layer 430, and recombination of the holes and the electrons in the organic electroluminescent layer 420 subsequently takes place to generate sufficient energy for exciting the fluorescent material of the organic electroluminescent layer 420, thereby resulting in emission of light.

By replacing the ITO film used in the conventional display panel with the flexible film of the nanomaterial for the anode 200, the display panel thus formed can be bent without the problem as encountered in the prior art that causes damage to the flexible film and the manufacturing costs can be reduced.

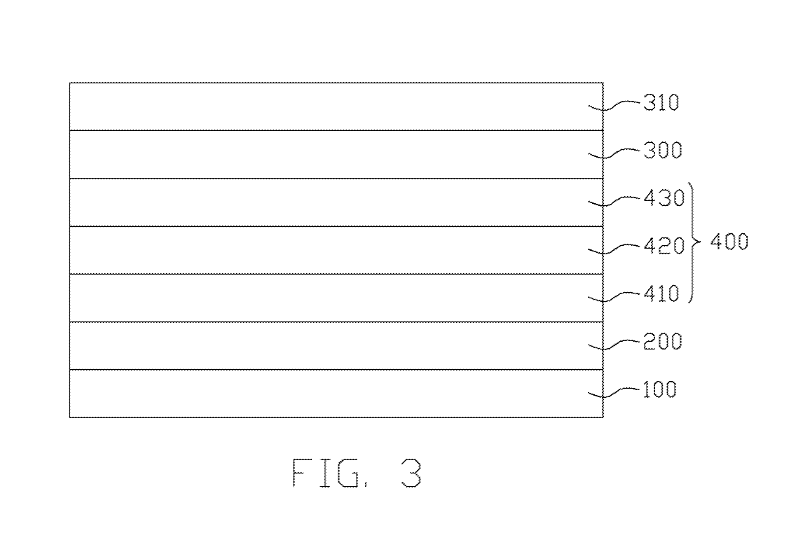

FIG. 3 illustrates the second exemplary embodiment of a display panel of the present disclosure. The display panel of the second exemplary embodiment differs from the previous exemplary embodiment in that the display panel further includes a reflective layer 310 disposed on the cathode 300 for reflecting light emitted from the organic electroluminescent layer 420. The cathode 300 is sandwiched between the reflective layer 310 and the electron transport layer 430, and can include the transparent nanomaterial. Hence, the light emitted from the organic electroluminescent layer 420 toward the reflective layer 310 can be reflected by the reflective layer 310 and be directed toward the lower substrate 100 so as to exit from the lower substrate 100.

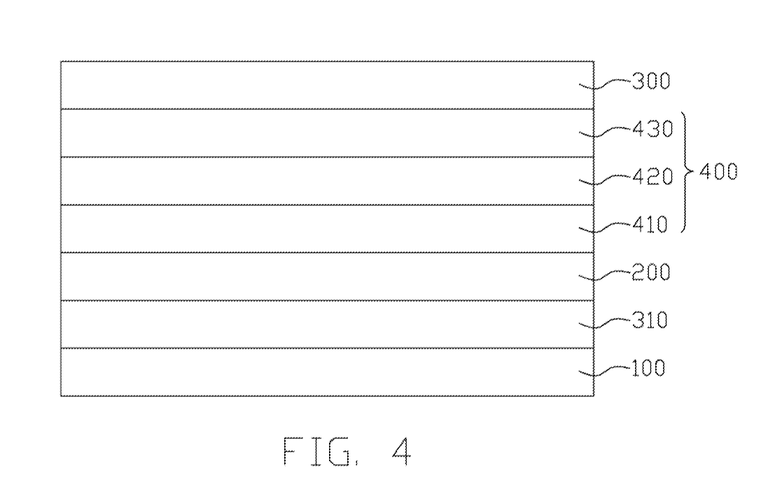

FIG. 4 illustrates the third exemplary embodiment of a display panel of the present disclosure. The display panel of the third exemplary embodiment differs from the second exemplary embodiment in that the reflective layer 310 is sandwiched between the lower substrate 100 and the organic electroluminescent layer 420. In this exemplary embodiment, the lower substrate 100 can be opaque. Moreover, the lower substrate 100 can be a colored opaque substrate or a colored transparent substrate. Hence, the light emitted from the organic electroluminescent layer 420 toward the reflective layer 310 can be reflected by the reflective layer 310 and be directed toward the cathode 300 so as to exit from the cathode 300.

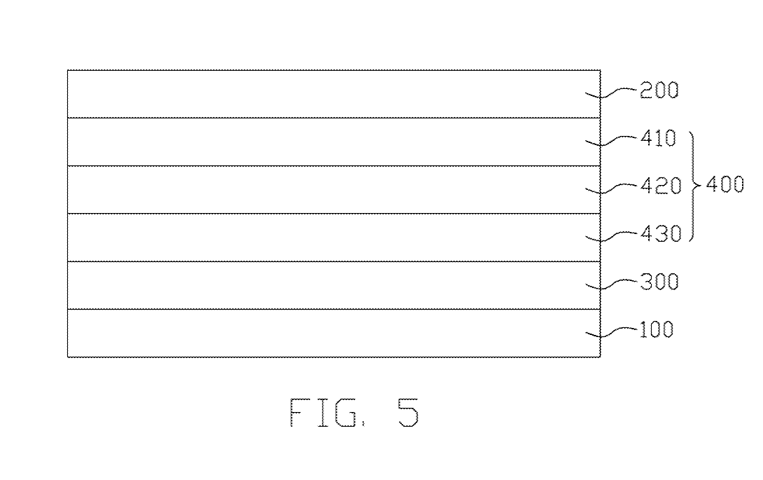

FIG. 5 illustrates the fourth exemplary embodiment of a display panel of the present disclosure. The display panel of the fourth exemplary embodiment differs from the first exemplary embodiment in that the cathode 300 is disposed on the lower substrate 100 instead of the anode 200. In this exemplary embodiment, the cathode 300 is sandwiched between the lower substrate 100 and the electron transport layer 430.

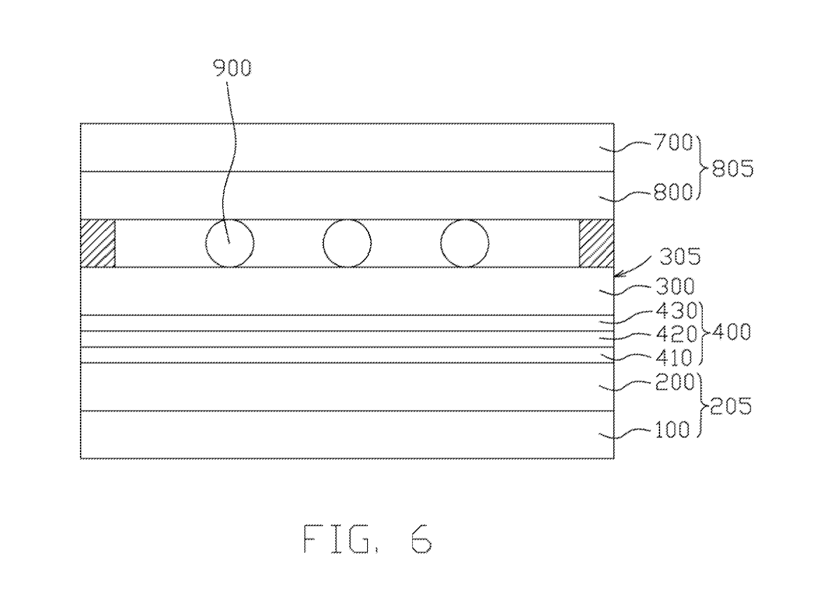

FIG. 6 illustrates the first exemplary embodiment of a touch-responsive display assembly of the present disclosure. The display assembly is an application of the display panel of the first exemplary embodiment. The display assembly includes: a first electrode unit 205, a second electrode unit 805 disposed over the first electrode unit 205, a third electrode unit 305 disposed between the first and second electrode units 205, 805, a spacer unit 900 of an insulator disposed between the second and third electrode units 805, 305, and the organic layered structure 400 disposed between the first and third electrode units 205, 305. At least one of the first and second electrode units 205, 805 is transparent. The second electrode unit 805 is electrically coupled to the third electrode unit 305 and cooperates with the third electrode unit 305 to form a touch panel that is touch-responsive. At least one of the first, second and third electrode units 205, 800, 305 includes a flexible film of the aforesaid conductive nanomaterial that contains the interconnected nanounits.

In this exemplary embodiment, the first electrode unit 205 includes the lower substrate 100 and the anode 200 of the display panel of the first exemplary embodiment, the third electrode unit 305 includes the cathode 300 of the display panel of the first exemplary embodiment, and the second electrode unit 805 includes an upper electrode 800 disposed on the spacer unit 900, and an upper substrate 700 disposed on the upper electrode 800.

In this exemplary embodiment, the upper electrode 800 includes the aforesaid nanomaterial so as to exhibit electric anisotropy, the upper substrate 700 is flexible, and the touch panel thus formed is resistive touch-responsive. As such, when the upper substrate 700 of the touch panel is touched to permit electrical connection between the upper electrode 800 and the cathode 300, which results in generation of a potential difference between two opposite detecting points on the touch panel attributed to the electric anisotropy property of the upper electrode 800, the location of the touch point can be determined based on the measured potential difference and the positions of the two detecting points.

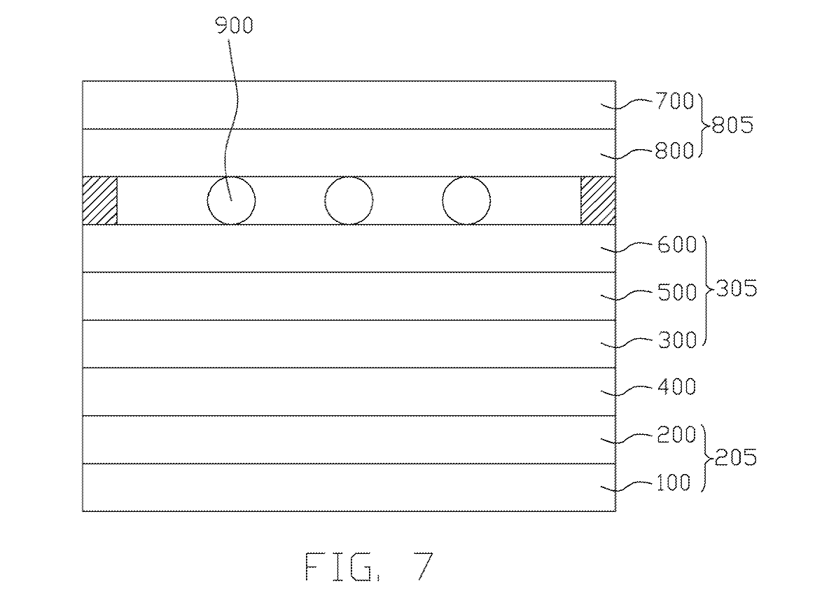

FIG. 7 illustrates the second exemplary embodiment of a touch-responsive display assembly of the present disclosure. The display assembly of the second exemplary embodiment differs from the display assembly of the first exemplary embodiment in that the third electrode unit 305 includes the cathode 300 disposed on the organic layered structure 400, a middle substrate 500, and a middle electrode 600 disposed on the middle substrate 500. The middle substrate 500 is sandwiched between the cathode 300 and the middle electrode 600.

For example, at least one of the upper electrode 800 and the middle electrode 600 is transparent and includes the nanomaterial. In the embodiment, the upper substrate 700 and the middle substrate 500 are flexible.

In sum, by using the conductive nanomaterial instead of the ITO as the material for the anode 200 or the cathode 300 of the flexible display panel of this disclosure, the aforesaid drawback associated with the prior art can be eliminated.

It is to be understood that even though numerous characteristics and advantages of the present embodiments have been set forth in the foregoing description, together with details of the structures and functions of the embodiments, the disclosure is illustrative only; and that changes may be made in detail, especially in matters of shape, size, and arrangement of parts, within the principles of the embodiments, to the full extent indicated by the broad general meaning of the terms in which the appended claims are expressed.

What is claimed is:

1. A display panel, comprising:
an anode;
a cathode disposed over said anode; and
an organic layered structure disposed between said anode and said cathode and including an organic electroluminescent layer that is emissive when a voltage is applied across said anode and said cathode;
wherein at least one of said anode and said cathode is made of a flexible film of a conductive nanomaterial that contains interconnected nanounits.

2. The display panel of claim 1, wherein said anode is transparent and includes the conductive nanomaterial.

3. The display panel of claim 2, further comprising a substrate and a reflective layer, said anode being sandwiched between said substrate and said organic layered structure, said cathode being sandwiched between said organic layered structure and said reflective layer, said reflecting layer being capable of reflecting light emitted from said organic electroluminescent layer.

4. The display panel of claim 1, wherein said flexible film exhibits electric anisotropy.

5. The display panel of claim 1, wherein said interconnected nanounits of said conductive nanomaterial are carbon nanotube bundles.

6. The display panel of claim 1, wherein said interconnected nanounits of said conductive nanomaterial extend along a direction.

7. The display panel of claim 1, further comprising a substrate and a reflective layer, said cathode being transparent, said reflective layer being disposed on said substrate and being sandwiched between said substrate and said anode for reflecting light emitted from said organic electroluminescent layer.

8. A touch-responsive display assembly, comprising:
a first electrode unit;
a second electrode unit disposed over said first electrode unit;
a third electrode unit disposed between said first and second electrode units; and
an organic layered structure disposed between said first and third electrode units and having an organic electroluminescent layer that is emissive when a voltage is applied across said first and third electrode units;
wherein said second electrode unit is electrically coupled to said third electrode unit and cooperates with said third electrode unit to form a touch panel that is touch-responsive; and
wherein at least one of said first, second and third electrode units includes a flexible film of a conductive nanomaterial that contains interconnected nanounits.

9. The touch-responsive display assembly of claim 8, wherein said first electrode unit includes a lower substrate and an anode disposed on said lower substrate, said third electrode unit includes a cathode, and said organic layered structure is sandwiched between said cathode and said anode.

10. The touch-responsive display assembly of claim 9, wherein said anode is transparent and includes the conductive nanomaterial.

11. The touch-responsive display assembly of claim 8, wherein said flexible film exhibits electric anisotropy.

12. The touch-responsive display assembly of claim 8, wherein said interconnected nanounits of said conductive nanomaterial are carbon nanotube bundles.

13. The touch-responsive display assembly of claim 8, wherein said interconnected nanounits of said conductive nanomaterial extend along a direction.

14. The touch-responsive display assembly of claim 8, further comprising a spacer unit of an insulator disposed between said second and third electrode units.

15. The touch-responsive display assembly of claim 14, wherein said third electrode unit further includes a middle substrate disposed on said cathode and a middle electrode sandwiched between said middle substrate and said spacer unit.

16. The touch-responsive display assembly of claim 15, wherein said second electrode unit includes an upper substrate and an upper electrode sandwiched between said spacer unit and said upper substrate, said spacer unit separating said upper and middle electrodes apart from each other.

17. The touch-responsive display assembly of claim 16, wherein at least one of said upper and middle electrodes includes the conductive nanomaterial.

18. The touch-responsive display assembly of claim 17, wherein said flexible film exhibits electric anisotropy.

19. The touch-responsive display assembly of claim 17, wherein said interconnected nanounits of said conductive nanomaterial are carbon nanotube bundles.

20. The touch-responsive display assembly of claim 17, wherein said interconnected nanounits of said conductive nanomaterial extend along a direction.
